(19) United States
(12) Patent Application Publication
(10) Pub. No.: US 2025/0370040 A1
(43) Pub. Date: Dec. 4, 2025

(54) ADAPTIVE WANDER MAGNITUDE MEASUREMENT

(71) Applicant: Microchip Technology Incorporated, Chandler, AZ (US)

(72) Inventors: Gary Qu Jin, Kanata (CA); Rahil Samani, Ottawa (CA); Kamran Rahbar, Kanata (CA)

(73) Assignee: Microchip Technology Incorporated, Chandler, AZ (US)

(21) Appl. No.: 18/800,307

(22) Filed: Aug. 12, 2024

Related U.S. Application Data
(60) Provisional application No. 63/653,579, filed on May 30, 2024.

(51) Int. Cl. G01R 31/317; H03L 7/08

(52) U.S. Cl. CPC G01R 31/31725; H03L 7/08

(57) ABSTRACT

Wander magnitude measurement by inputting a first input wander frequency into a timing phase locked loop circuit to produce a first output wander frequency, determining two parameters based on the first input wander frequency and the first output wander frequency, and using a least mean square (LMS) algorithm to estimate a wander transfer function based on the two parameters.

### PRIORITY STATEMENT

This application claims priority to U.S. Provisional Patent Application No. 63/653,579 filed May 30, 2024, the contents of which are hereby incorporated in their entirety.

### TECHNICAL FIELD

The present disclosure relates to timing systems, in particular, measurement of wander transfer function in timing systems.

### BACKGROUND

To obtain an accurate wander transfer function for timing systems, the wander magnitude is directly measured. The wander output is typically determined as:

$$y ( t ) = A sin ( ω t + θ ) + v ( t ) + b$$

In timing systems, wonder transfer function is typically measured by adding a single known frequency wander on an input clock and then measuring the output clock wander magnitude. After finishing the first measurement at a first known frequency, a second known frequency wander (different than the first frequency) is added on the input clock and then the output clock wander magnitude is measured. If the measure period is from t1 to t2, the common wonder magnitude measurement is to get peak-to-peak value of y(t) and then the magnitude will be half the value: A=½ (max(y(t))−min(y(t)). In this method, the noise is not filtered out and spikes in noise v (t) will cause measurement errors.

Another common way to measure wonder transfer function is to apply a fast fourier transform (FFT) algorithm sampling y(t) in the measurement period and find the magnitude of “A” at the measurement frequency f. A disadvantage of this method is that the observation period is an exact integer multiplier of 1/f. Otherwise, error will be introduced in the measurement. Where the data point being sampled is at a clock edge, it is difficult to measure the exact period 1/f. In other words, the measurement time is a multiple integer of wander period (FFT). Thus, this method introduces error in the measurement when the exact period 1/f is not precisely measured.

For timing systems that are subjected to excessive noise and anomalies (e.g. 1588 timing systems) these methods do not accurately provide a wander transfer function or the wander magnitude. Traditional wander transfer measurement techniques use extended periods of time to validate measurements.

There is a need for accurate measurement of wander output magnitude and wander transfer function across a range of frequency points, in particular, a method that runs inside timing products to measure timing system parameters in real time (e.g. measures phase delay).

### SUMMARY OF THE INVENTION

Aspects provide an adaptive wander output magnitude measurement method. With the adaptive method, the wander output magnitude can be accurately measured even if the input clock has small phase modulation or offset. The method can also be expanded to include measurement of device output wanders with multiple wander frequencies being applied at the same time, which may save time for the measurement of a wander transfer function for the device.

According to an aspect, there is provided a method comprising: inputting a first input wander frequency into a timing phase locked loop circuit to produce a first output wander frequency; determining a first parameter based on the first input wander frequency and the first output wander frequency; determining a second parameter based on the first input wander frequency and the first output wander frequency; and using a least mean square (LMS) algorithm to estimate a wander transfer function based on the first parameter and the second parameter.

An aspect as in the preceding paragraph, is a method comprising: inputting a second input wander frequency into the timing phase locked loop circuit to produce a second output wander frequency; determining a third parameter based on the second input wander frequency and the second output wander frequency; determining a fourth parameter based on the second input wander frequency and the second output wander frequency; and estimating a wander transfer function by a least mean square (LMS) algorithm based on the third parameter and the fourth parameter.

An aspect as in the preceding two paragraphs, is a method wherein the LMS algorithm adds the first parameter squared to the second parameter squared and takes the square root of the sum.

An aspect as in the preceding three paragraphs, is a method wherein the LMS algorithm is a normalized LMS algorithm or a recursive least squares (RLS) algorithm.

An aspect as in the preceding four paragraphs, is a method comprising: adjusting a filter coefficient to reduce a means square error between a desired estimated wander function and an actual estimated wander function, wherein the filter coefficient is based on noise cancellation, echo cancellation, or channel equalization.

An aspect as in the preceding five paragraphs, is a method wherein the first and second parameters are selected from a first wander magnitude, a first wander initial phase delay, or a first wander phase delay.

An aspect as in the preceding six paragraphs, is a method wherein the first parameter is a first wander magnitude multiplied by a cosine of a first wander initial phase delay, and the second parameter is a first wander magnitude multiplied by a sine of a first wander initial phase delay.

According to an aspect, there is provided a system comprising: a wander signal generator circuit; a timing phase locked loop circuit to receive from the wander signal generator circuit a first input wander signal having a first input frequency, and to output to a timing system the first output wander signal having a first output frequency; an adaptive wander measurement circuit to receive from the wander signal generator circuit the first input wander signal having the first frequency, and to receive from the timing system the first output wander signal having the first output frequency, the adaptive wander measurement circuit comprising: a processor; and a memory having instructions to cause the processor to: determine a first parameter based on the first input wander frequency and the first output wander frequency; determine a second parameter based on the first input wander frequency and the first output wander frequency; and estimate a wander transfer function by a least mean square (LMS) algorithm based on the first parameter and the second parameter.

An aspect as in the preceding paragraph, is a system wherein the timing phase locked loop circuit is to receive from the wander signal generator circuit a second input wander signal having a second input frequency, and is to output to a timing system the second output wander signal having a second output frequency; wherein the adaptive wander measurement circuit is to receive from the wander signal generator circuit the second input wander signal having the second frequency, and is to receive from the timing system the second output wander signal having the second output frequency; wherein the memory has instructions to cause the processor to: determine a third parameter based on the second input wander frequency and the second output wander frequency; determine a fourth parameter based on the second input wander frequency and the second output wander frequency; and estimate a wander transfer function by a least mean square (LMS) algorithm based on the third parameter and the fourth parameter.

An aspect as in the preceding two paragraphs, is a system wherein the LMS algorithm adds the first parameter squared to the second parameter squared and takes the square root of the sum.

An aspect as in the preceding three paragraphs, is a method wherein the LMS algorithm is a normalized LMS algorithm or a recursive least squares (RLS) algorithm.

An aspect as in the preceding four paragraphs, is a method wherein the instructions cause the processor to adjust a filter coefficient to reduce a means square error between a desired estimated wander function and an actual estimated wander function, wherein the filter coefficient is based on noise cancellation, echo cancellation, or channel equalization.

An aspect as in the preceding five paragraphs, is a method wherein the first and second parameters are selected from a first wander magnitude, a first wander initial phase delay, or a first wander phase delay.

An aspect as in the preceding six paragraphs, is a method wherein the first parameter is a first wander magnitude multiplied by the cosine of a first wander initial phase delay, and the second parameter is a first wander magnitude multiplied by the sine of a first wander initial phase delay.

According to an aspect, there is provided a device comprising: a timing phase locked loop circuit to receive a first input wander signal having a first input frequency, and to output a first output wander signal having a first output frequency; an adaptive wander measurement circuit to receive the first input wander signal having the first frequency, and to receive from the timing phase locked loop circuit the first output wander signal having the first output frequency, the adaptive wander measurement circuit comprising: a processor; and a memory having instructions to cause the processor to: determine a first parameter based on the first input wander frequency and the first output wander frequency; determine a second parameter based on the first input wander frequency and the first output wander frequency; and estimate a wander transfer function by a least mean square (LMS) algorithm based on the first parameter and the second parameter.

An aspect as in the preceding paragraph is a device wherein the timing phase locked loop circuit is to receive a second input wander signal having a second input frequency, and is to output the second output wander signal having a second output frequency; wherein the adaptive wander measurement circuit is to receive the second input wander signal having the second frequency, and is to receive the second output wander signal having the second output frequency; wherein the memory has instructions to cause the processor to: determine a third parameter based on the second input wander frequency and the second output wander frequency; determine a fourth parameter based on the second input wander frequency and the second output wander frequency; and estimate a wander parameter by a least mean square (LMS) algorithm based on the third parameter and the fourth parameter.

An aspect as in the preceding two paragraphs is a device wherein the LMS algorithm adds the first parameter squared to the second parameter squared and takes the square root of the sum.

An aspect as in the preceding three paragraphs is a device wherein the LMS algorithm is a normalized LMS algorithm or a recursive least squares (RLS) algorithm.

An aspect as in the preceding four paragraphs is a device wherein the instructions cause the processor to adjust a filter coefficient to reduce a means square error between a desired estimated wander function and an actual estimated wander function, wherein the filter coefficient is based on noise cancellation, echo cancellation, or channel equalization.

An aspect as in the preceding five paragraphs is a device wherein the first and second parameters are selected from a first wander magnitude, a first wander initial phase delay, or a first wander phase delay.

An aspect as in the preceding six paragraphs is a device wherein the first parameter is a first wander magnitude multiplied by a cosine of a first wander initial phase delay, and the second parameter is a first wander magnitude multiplied by a sine of a first wander initial phase delay.

### BRIEF DESCRIPTION OF THE DRAWINGS

The figures illustrate examples of a Least Mean Square (LMS) adaptive method to measure wander output magnitude.

FIG. 1 shows a block diagram of a timing integrated circuit implementing the LMS adaptive method for use with a timing system.

FIG. 2 shows a block diagram of an implementation of the LMS adaptive method on a chip.

FIG. 3 shows an implementation using an adaptive lease mean square (LMS) method.

FIG. 4 shows an implementation using an adaptive lease mean square (LMS) method for multi-wander estimation.

FIG. 5 is a block diagram of circuitry that may be used to implement various functions, operations, acts, processes, and methods disclosed herein.

FIG. 6 shows a flow chart for a method for measurement of wander output magnitude and wander transfer function across a range of frequency points.

The reference number for any illustrated element that appears in multiple different figures has the same meaning across the multiple figures, and the mention or discussion herein of any illustrated element in the context of any particular figure also applies to each other figure, if any, in which that same illustrated element is shown.

### DESCRIPTION

According to an aspect, there is provided a Least Mean Square (LMS) adaptive method to measure wander output magnitude. With the LMS adaptive method, the wander output magnitude can be accurately measured even if the input clock has small phase modulation or offset. The method can also be expanded to include measurement of device output wanders with multiple wander frequencies being applied at the same time, which may save time for the measurement of a wander transfer function for the device.

The LMS adaptive method accurately estimates wander magnitude, even with unknown initial phase and with small modulation and frequency offset due to measurement clock offset. Accurate wander measurement may be obtained under non-ideal conditions, such as unknow phase delay and small modulation. The adaptive wander output magnitude measurement method may also save time for wander transfer function measurement because multiple wander frequencies may be measured at the same time. In particular, the wander transfer measurement may be quickly obtained by simultaneously measuring multiple wander frequencies. The initial condition and parameters may be determined for the fast convergence and final measurement accuracy. The LMS adaptive method adapts so that the accuracy can be improved with increasing observations.

To measure wander magnitude “A” in the observation y(t)=A*sin (ωt+θ)+v(t)+b, instead of measuring A directly, w1=A sinθ, w2=Acosθ and w0=b are measured jointly with a Least Mean Square (LMS) adaptive method. The wander magnitude “A” is estimated as the sqrt (w1\hat{ }2+w2\hat{ }2), wherein the impact of initial phase θ may be ignored even if it has a small modulation θ(t). The LMS adaptive method takes the whole observation period as measurement and filters out the noise.

Previously, the wander output magnitude is: γ(t)=A sin (ωt+θ)+v(t)+b

However, the problem may be rewritten as:

$$y ( t ) = {w}_{1} sin ( ω t ) + {w}_{2} cos ( ω t ) + v ( t ) + {w}_{0}$$

Where w₀=b w₁=A cos (θ) and w₂=A sin (θ), and

$$A = \sqrt{{w}_{1}^{2} + {w}_{2}^{2}} , θ = {tan}^{- 1} ( \frac{{w}_{2}}{{w}_{1}} ) .$$

The adaptive method is to join estimation of all parameters: wₖ, k=0,1,2.

$$\hat{W} = \hat{W} + μ {ex}_{k}$$

$$With e = y ( {t}_{k} ) - {x}_{k}^{T} \hat{W}$$

$$And \hat{W} = [ \begin{matrix} \\ \\ \end{matrix} ] , {x}_{k} = [ \begin{matrix}1 \\ sin ( ω {t}_{k} ) \\ cos ( ω {t}_{k} )\end{matrix} ]$$

The LMS adaptive method identifies related parameters in a timing system, based on observed output data, to accurately estimate the wander magnitude. The LMS adaptive method provides a joint estimation of all system parameters, not just the wander magnitude. The LMS adaptive method uses an adaptive LMS (Least Mean Square) joint parameter estimation with proper initialization. It is adaptive to muti-frequency wander magnitude estimations. The LMS adaptive method is robust to environmental variations (noise, drift, without limitation).

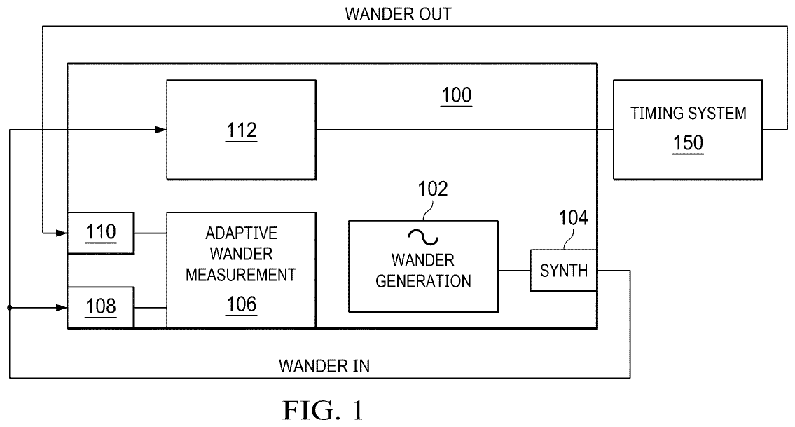

FIG. 1 shows a block diagram of a timing circuit 100 implementing the adaptive method for use with a timing system 150. A wander generator circuit 102 generates a wander function and sends it through a synthesizer circuit 104. The wander function is input to: (1) an adaptive wander measurement circuit 106 via an input 108; and (2) a phase locked loop circuit 112. The phase locked loop circuit 112 may be a digital phase locked loop circuit or a timing phase locked loop circuit. The phase locked loop circuit 112 outputs the wander function to the timing system 150. The wander output from the timing system 150 is fed into the adaptive wander measurement circuit 106 via an input 110. The adaptive wander measurement circuit 106 may implement a Least Mean Square (LMS) adaptive algorithm, a normalized LMS algorithm, or a recursive least squares (RLS) algorithm.

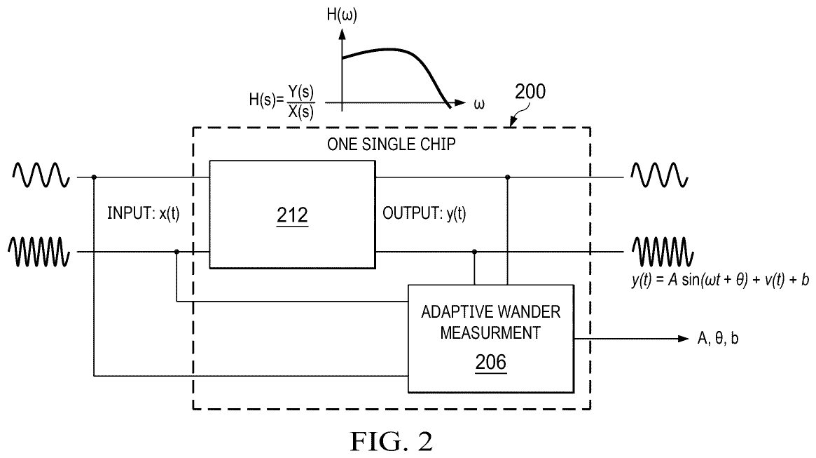

FIG. 2 shows a block diagram of an implementation of the adaptive method on a chip 200. It can be fitted on a single chip, or used separately. Two different wander frequencies are input (x (t)) into: (1) a phase locked loop circuit 212, which produces output (y(t)); and (2) an adaptive wander measurement circuit 206. The adaptive wander measurement circuit 206 also takes as input the output (y(t)) produced by the phase locked loop circuit 212. The adaptive wander measurement circuit 206 outputs the parameters for the wander estimation, which may include a wander magnitude (A), a wander initial phase delay (θ), or a wander phase delay (b).

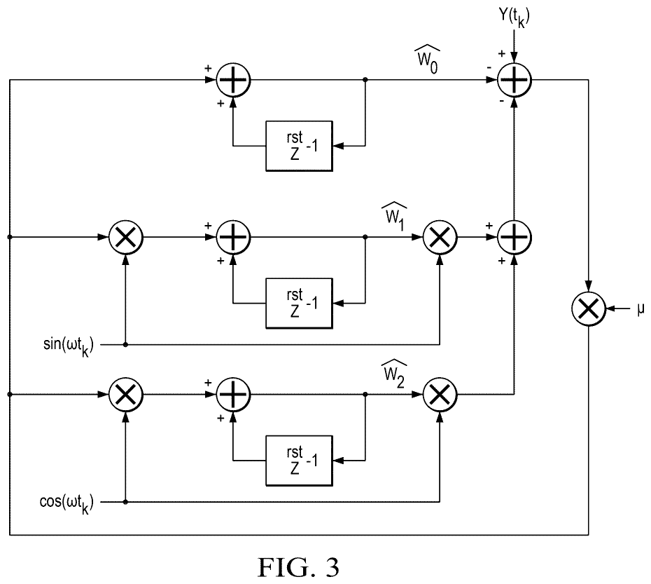

FIG. 3 shows an implementation using an adaptive least mean square (LMS) method, which may improve precision with more data being collected, and may provide an accurate estimation of wander magnitude even if there is modulation θ(t). For stability:

$$μ < \sqrt{{x}_{k}^{T} {x}_{k}} = \sqrt{2}$$

Considering both performance accuracy and convergence, we have μ to be set between 0.001 and 0.1. The initial values are: w₀=y(t0) and w₁=w₂=0.

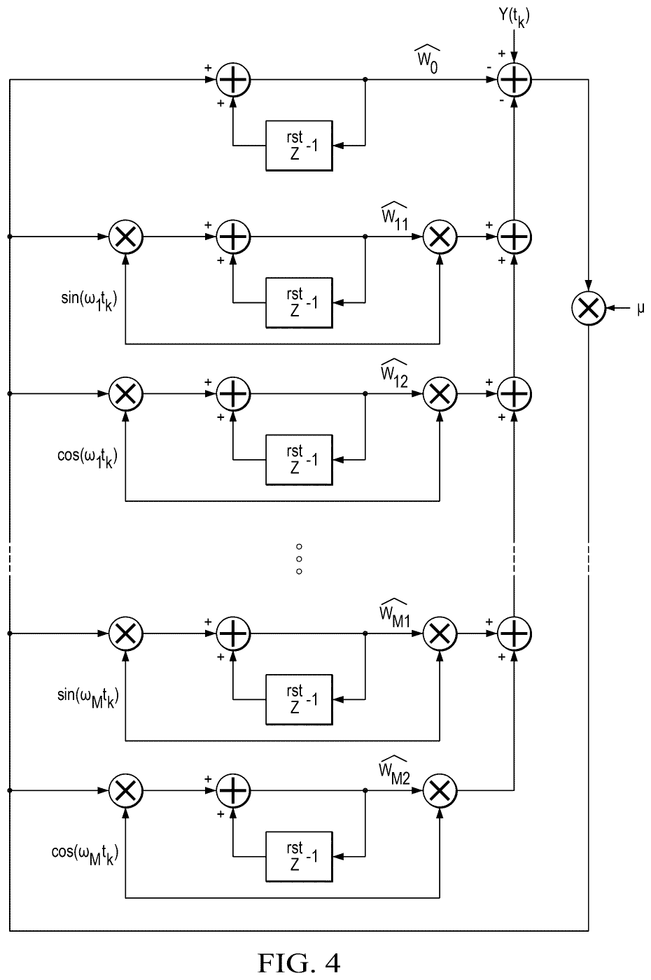

FIG. 4 shows an implementation using an adaptive lease mean square (LMS) method for multi-wander estimation.

$$y ( t ) = {\sum }_{k = 1}^{M} {A}_{k} sin ( {ω}_{k} t + {θ}_{k} ( t ) ) + v ( t ) + {w}_{0}$$

The adaptive update will still be:

$$\hat{W} = \hat{W} + μ {ex}_{k}$$

$$With e = y ( {t}_{k} ) - {x}_{k}^{T} \hat{W} and \hat{W} = [ \begin{matrix} \\ \\ \\ ⋮ \\ \\ \end{matrix} ] , {x}_{k} = [ \begin{matrix}1 \\ sin ( {ω}_{1} {t}_{k} ) \\ cos ( {ω}_{1} {t}_{k} ) \\ ⋮ \\ sin ( {ω}_{M} {t}_{k} ) \\ cos ( {ω}_{M} {t}_{k} )\end{matrix} ]$$

$$Finally ,$$

$$= \sqrt{} , = {tan}^{- 1} , k = 1 , 2 , ... , M$$

The adaptive lease mean square (LMS) method can be used for wander transfer measurement of timing products. It can also be embedded inside SoC timing products as a self diagnostic feature or to measure separate timing system parameters (e.g. phase delay). The adaptive lease mean square (LMS) method is an adaptive filter algorithm that iteratively adjusts the filter coefficients based on minimizing the mean square error between the desired output and the actual output. LMS algorithm has a simple computational structure, which makes it suitable for real-time signal processing applications and adaptive filters such as noise cancellation, echo cancellation, and channel equalization. If the LMS algorithm suffers from slow convergence speed or becoming trapped in local minima, these limitations can be addressed by using variants such as the Normalized LMS or the RLS (Recursive Least Squares) algorithm.

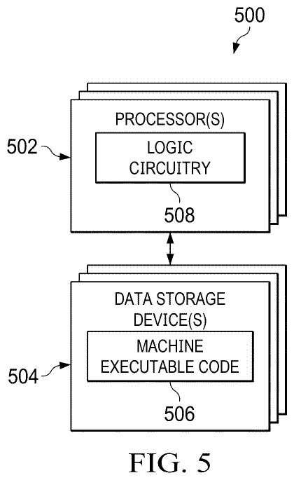

FIG. 5 is a block diagram of circuitry 500 that, in some aspects, may be used to implement various functions, operations, acts, processes, and/or methods disclosed herein. The circuitry 500 includes one or more processors 502 (sometimes referred to herein as “processors 502”) operably coupled to one or more data storage devices (sometimes referred to herein as “storage 504”). The storage 504 includes machine executable code 506 stored thereon and the processors 502 include logic circuitry 508. The machine executable code 506 includes information describing functional elements that may be implemented by (e.g., performed by) the logic circuitry 508. The logic circuitry 508 is adapted to implement (e.g., perform) the functional elements described by the machine executable code 506. The circuitry 500, when executing the functional elements described by the machine executable code 506, may be considered as specific purpose hardware configured for carrying out functional elements disclosed herein. In some aspects the processors 502 may perform the functional elements described by the machine executable code 506 sequentially, concurrently (e.g., on one or more different hardware platforms), or in one or more parallel process streams.

When implemented by logic circuitry 508 of the processors 502, the machine executable code 506 adapts the processors 502 to perform operations of aspects disclosed herein. For example, the machine executable code 506 may adapt the processors 502 to perform at least a portion or a totality of the adaptive wander method of FIG. 3, and/or the adaptive wander method of FIG. 4. As another example, the machine executable code 506 may adapt the processors 502 to perform at least a portion or a totality of the operations discussed for the adaptive wander measurement circuit of FIGS. 1 and 2. As a specific, non-limiting example, the machine executable code 506 may adapt the processors 502 to perform at least a portion of the adaptive wander measurement operations discussed herein.

The processors 502 may include a general purpose processor, a specific purpose processor, a central processing unit (CPU), a microcontroller, a programmable logic controller (PLC), a digital signal processor (DSP), an application specific integrated circuit (ASIC), a field-programmable gate array (FPGA) or other programmable logic device, discrete gate or transistor logic, discrete hardware components, other programmable device, or any combination thereof designed to perform the functions disclosed herein. A general-purpose computer including a processor is considered a specific-purpose computer while the general-purpose computer is configured to execute functional elements corresponding to the machine executable code 506 (e.g., software code, firmware code, hardware descriptions) related to aspects of the present disclosure. It is noted that a general-purpose processor (may also be referred to herein as a host processor or simply a host) may be a microprocessor, but in the alternative, the processors 502 may include any conventional processor, controller, microcontroller, or state machine. The processors 502 may also be implemented as a combination of computing devices, such as a combination of a DSP and a microprocessor, a plurality of microprocessors, one or more microprocessors in conjunction with a DSP core, or any other such configuration.

In some aspects the storage 504 includes volatile data storage (e.g., random-access memory (RAM)), non-volatile data storage (e.g., Flash memory, a hard disc drive, a solid state drive, erasable programmable read-only memory (EPROM), without limitation). In some aspects the processors 502 and the storage 504 may be implemented into a single device (e.g., a semiconductor device product, a system on chip (SOC), without limitation). In some aspects the processors 502 and the storage 504 may be implemented into separate devices.

In some aspects the machine executable code 506 may include computer-readable instructions (e.g., software code, firmware code). By way of non-limiting example, the computer-readable instructions may be stored by the storage 504, accessed directly by the processors 502, and executed by the processors 502 using at least the logic circuitry 508. Also by way of non-limiting example, the computer-readable instructions may be stored on the storage 504, transferred to a memory device (not shown) for execution, and executed by the processors 502 using at least the logic circuitry 508. Accordingly, in some aspects the logic circuitry 508 includes electrically configurable logic circuitry 508.

In some aspects the machine executable code 506 may describe hardware (e.g., circuitry) to be implemented in the logic circuitry 508 to perform the functional elements. This hardware may be described at any of a variety of levels of abstraction, from low-level transistor layouts to high-level description languages. At a high-level of abstraction, a hardware description language (HDL) such as an IEEE Standard hardware description language (HDL) may be used. By way of non-limiting examples, Verilog™, System Verilog™ or very large scale integration (VLSI) hardware description language (VHDL™) may be used.

HDL descriptions may be converted into descriptions at any of numerous other levels of abstraction as desired. As a non-limiting example, a high-level description can be converted to a logic-level description such as a register-transfer language (RTL), a gate-level (GL) description, a layout-level description, or a mask-level description. As a non-limiting example, micro-operations to be performed by hardware logic circuits (e.g., gates, flip-flops, registers, without limitation) of the logic circuitry 508 may be described in a RTL and then converted by a synthesis tool into a GL description, and the GL description may be converted by a placement and routing tool into a layout-level description that corresponds to a physical layout of an integrated circuit of a programmable logic device, discrete gate or transistor logic, discrete hardware components, or combinations thereof. Accordingly, in some aspects, the machine executable code 506 may include an HDL, an RTL, a GL description, a mask level description, other hardware description, or any combination thereof.

In aspects where the machine executable code 506 includes a hardware description (at any level of abstraction), a system (not shown, but including the storage 504) may be configured to implement the hardware description described by the machine executable code 506. By way of non-limiting example, the processors 502 may include a programmable logic device (e.g., an FPGA or a PLC) and the logic circuitry 508 may be electrically controlled to implement circuitry corresponding to the hardware description into the logic circuitry 508. Also, by way of non-limiting example, the logic circuitry 508 may include hard-wired logic manufactured by a manufacturing system (not shown, but including the storage 504) according to the hardware description of the machine executable code 506.

Regardless of whether the machine executable code 506 includes computer-readable instructions or a hardware description, the logic circuitry 508 is adapted to perform the functional elements described by the machine executable code 506 when implementing the functional elements of the machine executable code 506. It is noted that although a hardware description may not directly describe functional elements, a hardware description indirectly describes functional elements that the hardware elements described by the hardware description are capable of performing.

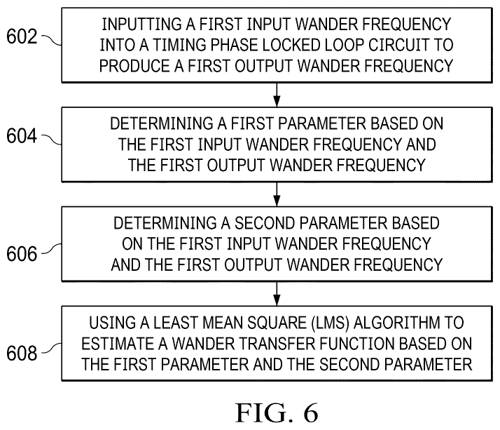

FIG. 6 shows a flow chart for a method for measurement of wander output magnitude and wander transfer function across a range of frequency points. A first input wander frequency is input 602 into a timing phase locked loop circuit to produce a first output wander frequency. A first parameter is determined 604 based on the first input wander frequency and the first output wander frequency. A second parameter is determined 606 based on the first input wander frequency and the first output wander frequency. A least mean square (LMS) algorithm is used 608 to estimate a wander transfer function based on the first parameter and the second parameter.

Although examples have been described above, other variations and examples may be made from this disclosure without departing from the spirit and scope of these disclosed examples.

1. A method comprising:
inputting a first input wander frequency into a timing phase locked loop circuit to produce a first output wander frequency;
determining a first parameter based on the first input wander frequency and the first output wander frequency;
determining a second parameter based on the first input wander frequency and the first output wander frequency; and
using a least mean square (LMS) algorithm to estimate a wander transfer function based on the first parameter and the second parameter.

2. The method as in claim 1, comprising:
inputting a second input wander frequency into the timing phase locked loop circuit to produce a second output wander frequency;
determining a third parameter based on the second input wander frequency and the second output wander frequency;
determining a fourth parameter based on the second input wander frequency and the second output wander frequency; and
estimating a wander transfer function by a least mean square (LMS) algorithm based on the third parameter and the fourth parameter.

3. The method as in claim 1, wherein the LMS algorithm adds the first parameter squared to the second parameter squared and takes the square root of the sum.

4. The method as in claim 1, wherein the LMS algorithm is a normalized LMS algorithm or a recursive least squares (RLS) algorithm.

5. The method as in claim 1, comprising: adjusting a filter coefficient to reduce a means square error between a desired estimated wander function and an actual estimated wander function, wherein the filter coefficient is based on noise cancellation, echo cancellation, or channel equalization.

6. The method as in claim 1, wherein the first and second parameters are selected from a first wander magnitude, a first wander initial phase delay, or a first wander phase delay.

7. The method as in claim 1, wherein the first parameter is a first wander magnitude multiplied by a cosine of a first wander initial phase delay, and the second parameter is a first wander magnitude multiplied by a sine of a first wander initial phase delay.

8. A system comprising:
a wander signal generator circuit;
a timing phase locked loop circuit to receive from the wander signal generator circuit a first input wander signal having a first input frequency, and to output to a timing system the first output wander signal having a first output frequency;
an adaptive wander measurement circuit to receive from the wander signal generator circuit the first input wander signal having the first frequency, and to receive from the timing system the first output wander signal having the first output frequency, the adaptive wander measurement circuit comprising:
a processor; and
a memory having instructions to cause the processor to:
determine a first parameter based on the first input wander frequency and the first output wander frequency;
determine a second parameter based on the first input wander frequency and the first output wander frequency; and
estimate a wander transfer function by a least mean square (LMS) algorithm based on the first parameter and the second parameter.

9. The system as in claim 8,
wherein the timing phase locked loop circuit is to receive from the wander signal generator circuit a second input wander signal having a second input frequency, and is to output to a timing system the second output wander signal having a second output frequency;
wherein the adaptive wander measurement circuit is to receive from the wander signal generator circuit the second input wander signal having the second frequency, and is to receive from the timing system the second output wander signal having the second output frequency;
wherein the memory has instructions to cause the processor to:
determine a third parameter based on the second input wander frequency and the second output wander frequency;
determine a fourth parameter based on the second input wander frequency and the second output wander frequency; and
estimate a wander transfer function by a least mean square (LMS) algorithm based on the third parameter and the fourth parameter.

10. The system as in claim 8, wherein the LMS algorithm adds the first parameter squared to the second parameter squared and takes the square root of the sum.

11. The system as in claim 8, wherein the LMS algorithm is a normalized LMS algorithm or a recursive least squares (RLS) algorithm.

12. The system as in claim 8, wherein the instructions cause the processor to adjust a filter coefficient to reduce a means square error between an estimated wander function and an actual estimated wander function, wherein the filter coefficient is based on noise cancellation, echo cancellation, or channel equalization.

13. The system as in claim 8, wherein the first and second parameters are selected from a first wander magnitude, a first wander initial phase delay, or a first wander phase delay.

14. The system as in claim 8, wherein the first parameter is a first wander magnitude multiplied by the cosine of a first wander initial phase delay, and a second wander magnitude multiplied by the sine of a first wander initial phase delay.

15. A device comprising:
a timing phase locked loop circuit to receive a first input wander signal having a first input frequency, and to output a first output wander signal having a first output frequency;
an adaptive wander measurement circuit to receive the first input wander signal having the first frequency, and to receive from the timing phase locked loop circuit the first output wander signal having the first output frequency, the adaptive wander measurement circuit comprising:
a processor; and
a memory having instructions to cause the processor to:
determine a first parameter based on the first input wander frequency and the first output wander frequency;
determine a second parameter based on the first input wander frequency and the first output wander frequency; and
estimate a wander transfer function by a least mean square (LMS) algorithm based on the first parameter and the second parameter.

16. The device as in claim 15,
wherein the timing phase locked loop circuit is to receive a second input wander signal having a second input frequency, and is to output the second output wander signal having a second output frequency;
wherein the adaptive wander measurement circuit is to receive the second input wander signal having the second frequency, and is to receive the second output wander signal having the second output frequency;
wherein the memory has instructions to cause the processor to:
determine a third parameter based on the second input wander frequency and the second output wander frequency;
determine a fourth parameter based on the second input wander frequency and the second output wander frequency; and
estimate a wander transfer function by a least mean square (LMS) algorithm based on the third parameter and the fourth parameter.

17. The device as in claim 15, wherein the LMS algorithm adds the first parameter squared to the second parameter squared and takes the square root of the sum.

18. The device as in claim 15, wherein the LMS algorithm is a normalized LMS algorithm or a recursive least squares (RLS) algorithm.

19. The device as in claim 15, wherein the instructions cause the processor to adjust a filter coefficient to reduce a means square error between an estimated wander function and an actual estimated wander function, wherein the filter coefficient is based on noise cancellation, echo cancellation, or channel equalization.

20. The device as in claim 15, wherein the first and second parameters are selected from a first wander magnitude, a first wander initial phase delay, or a first wander phase delay.

21. The device as in claim 15, wherein the first parameter is a first wander magnitude multiplied by a cosine of a first wander initial phase delay, and the second parameter is a first wander magnitude multiplied by a sine of a first wander initial phase delay.
